(19) United States
(12) Patent Application Publication
(10) Pub. No.: US 2019/0211234 A1
(43) Pub. Date: Jul. 11, 2019

(54) ADHESIVE LAYER FOR FLEXIBLE IMAGE DISPLAY DEVICES, LAMINATE FOR FLEXIBLE IMAGE DISPLAY DEVICES, AND FLEXIBLE IMAGE DISPLAY DEVICE

(71) Applicant: NITTO DENKO CORPORATION, Ibaraki-shi, Osaka (JP)

(72) Inventors: Mizue Yamasaki, Ibaraki-shi (JP); Yusuke Toyama, Ibaraki-shi (JP); Yu Morimoto, Ibaraki-shi (JP)

(73) Assignee: NITTO DENKO CORPORATION, Ibaraki-shi, Osaka (JP)

(21) Appl. No.: 16/325,552

(22) PCT Filed: Aug. 2, 2017
(86) PCT No.: PCT/JP2017/028036

§ 371 Date: Feb. 14, 2019

(30) Foreign Application Priority Data
Aug. 15, 2016 (JP) 2016-159384

(51) Int. Cl. C09J 7/40; C09J 133/24; G02B 5/30; G02F 1/1333; G09F 9/30; H01L 27/32; H01L 51/50; H05B 33/02

(52) U.S. Cl. CPC C09J 7/40; C09J 133/24; G02B 5/3025; H05B 33/02; G09F 9/301; H01L 27/32; H01L 51/5012; G02F 1/133305

(57) ABSTRACT

The purpose of the present invention is to provide: a pressure-sensitive adhesive layer for a flexible image display device which exhibits excellent bending resistance and adhesiveness, and which does not peel or break even after repeated bending; a laminate for a flexible image display device which includes the pressure-sensitive adhesive layer for a flexible image display device; and a flexible image display device in which the laminate for a flexible image display device is provided. A pressure-sensitive adhesive layer for a flexible image display device formed from a pressure-sensitive adhesive composition containing a (meth)acrylic polymer, wherein a weight average molecular weight (Mw) of the (meth)acrylic polymer is from 1,000,000 to 2,500,000, and a glass transition temperature (Tg) of the pressure-sensitive adhesive layer is 0° C. or less.

### TECHNICAL FIELD

The present invention relates to a pressure-sensitive adhesive layer for a flexible image display device, a laminate for a flexible image display device, and a flexible image display device in which the laminate for a flexible image display device is disposed.

### BACKGROUND ART

As an example of a conventional image display device including an organic EL, one having a configuration shown in FIG. 1 is exemplified. In this image display device, an optical laminate 20 is provided on the viewing side of an organic EL display panel 10 and a touch panel 30 is provided on the viewing side of the optical laminate 20. The optical laminate 20 includes a polarizer 1 having protective films 2-1 and 2-2 bonded on both sides thereof and a retardation film 3, and the polarizer 1 is provided on the viewing side of the retardation film 3. Further, in the touch panel 30, transparent conductive films 4-1 and 4-2 having a structure in which base material films 5-1 and 5-2 and transparent conductive layers 6-1 and 6-2 are laminated are disposed with an interposed spacer 7 (see, for example, Patent Document 1).

In such an image display device, a foldable flexible image display device is required, and a pressure-sensitive adhesive layer used for the flexible image display device is being studied.

### PRIOR ART DOCUMENT

### Patent Document

Patent Document 1: JP-A-2014-157745

### SUMMARY OF THE INVENTION

### Problems to be Solved by the Invention

The conventional organic EL display device as disclosed in Patent Document 1 is not designed with folding in mind. When a plastic film is used as a base material for an organic EL display panel, bendability can be imparted to the organic EL display panel. In addition, even when the plastic film is used for the touch panel and incorporated in the organic EL display panel, bendability can be imparted to the organic EL display panel. However, a problem of hindering the bendability of the organic EL display device occurs due to an optical laminate obtained by laminating a conventional polarizer, a protective film thereof, and a retardation film laminated on the organic EL display panel.

The purpose of the present invention is to provide: a pressure-sensitive adhesive layer for a flexible image display device, which exhibits excellent bending resistance and adhesiveness, and which does not peel or break even after repeated bending; a laminate for a flexible image display device, which includes the pressure-sensitive adhesive layer for a flexible image display device; and a flexible image display device in which the laminate for a flexible image display device is disposed.

### Means for Solving the Problems

The pressure-sensitive adhesive layer for a flexible image display device of the present invention is a pressure-sensitive adhesive layer for a flexible image display device formed from a pressure-sensitive adhesive composition containing a (meth)acrylic polymer, wherein a weight average molecular weight (Mw) of the (meth)acrylic polymer is from 1,000,000 to 2,500,000, and a glass transition temperature (Tg) of the pressure-sensitive adhesive layer is 0° C. or less.

The pressure-sensitive adhesive layer for a flexible image display device of the present invention preferably has a storage elastic modulus G′ at 25° C. of 1.0 MPa or less.

In the pressure-sensitive adhesive layer for a flexible image display device of the present invention, an adhesive strength to a polarizing film is preferably 5 to 40 N/25 mm.

The laminate for a flexible image display device of the present invention preferably has the pressure-sensitive adhesive layer for a flexible image display device, a protective film of a transparent resin material, and a polarizer in this order.

It is preferable that the flexible image display device of the present invention includes the laminate for a flexible image display device and an organic EL display panel, wherein the laminate for a flexible image display device is disposed on a viewing side of the organic EL display panel.

### Effect of the Invention

The pressure-sensitive adhesive layer for a flexible image display device of the present invention is useful because it does not peel off even after repeated bending and can form a laminate for a flexible image display device excellent in bending resistance and adhesiveness, and it is possible to obtain a flexible image display device in which the laminate for a flexible image display device is disposed.

Embodiments of a pressure-sensitive adhesive layer for a flexible image display device, a laminate for a flexible image display device, and a flexible image display device according to the present invention will be described in detail below with reference to the drawings and the like.

### BRIEF DESCRIPTION OF THE DRAWINGS

FIG. 1 is a cross-sectional view showing a conventional organic EL display device.

FIG. 2 is a cross-sectional view showing a flexible image display device according to another embodiment of the present invention.

FIG. 3 is a cross-sectional view showing an evaluation sample used in examples.

FIG. 4 is a view showing a method for measuring folding endurance.

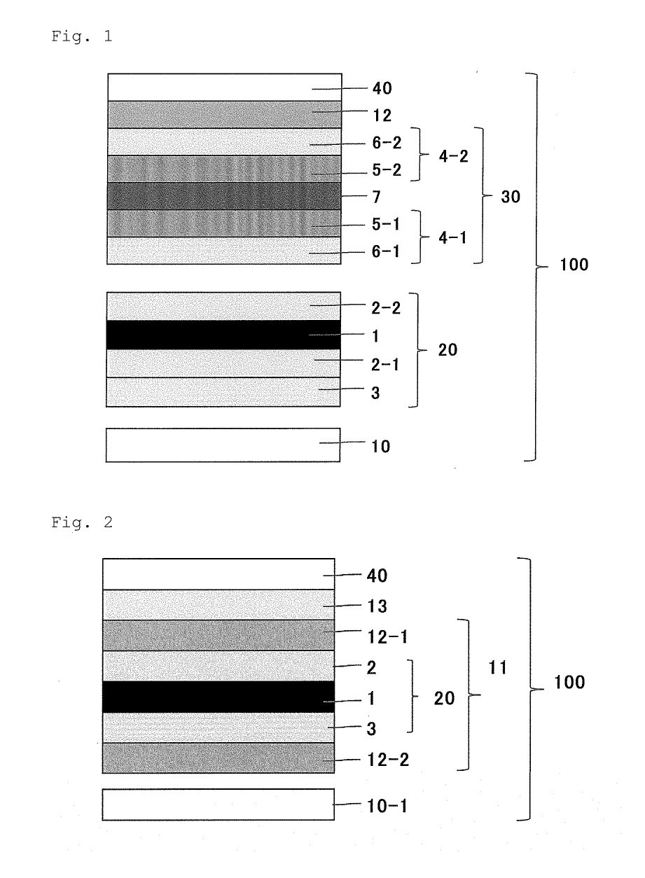

### MODE FOR CARRYING OUT THE INVENTION

### [Laminate for Flexible Image Display Device]

It is preferable that the laminate for a flexible image display device of the present invention has (laminates) at least a pressure-sensitive adhesive layer for a flexible image display device, a protective film formed of a transparent resin material, and a polarizer in this order on the viewing side. In this configuration, a retardation film or the like may be appropriately provided.

A thickness of the laminate for a flexible image display is preferably 92 μm or less, more preferably 60 μm or less, even more preferably 10 to 50 μm. A preferred embodiment is within the above range without hindering the bending.

It is preferable that the polarizer has a protective film on at least one side of the polarizer, and it is preferable that the polarizer is bonded with an adhesive layer. Examples of the adhesive forming the adhesive layer include isocyanate-based adhesives, polyvinyl alcohol-based adhesives, gelatin-based adhesives, vinyl type latex-based, aqueous-based polyester and the like. The adhesive is usually used as an adhesive made of aqueous solution, and usually contains 0.5 to 60% by weight of a solid content. Besides the above, as an adhesive for the polarizer and the protective film, an ultraviolet curable adhesive, an electron beam-curable adhesive and the like can be mentioned. The adhesive for electron beam curing type polarizing film shows suitable adhesion property to various protective films mentioned above. The adhesive used in the present invention may contain a metal compound filler. In the present invention, a polarizer and a protective film bonded with an adhesive (layer) may be sometimes referred to as a polarizing film (polarizing plate).

### <Polarizer>

In the polarizer that can be used in the present invention, a polyvinyl alcohol (PVA) based resin which is stretched by a stretching step such as air stretching (dry stretching) or a stretching step in an aqueous boric acid and in which iodine is aligned can be used.

Typically, as a method for producing the polarizer, there is a production method including a step of dyeing a single layer body of a PVA-based resin and a step of stretching such a single layer body as described in JP-A-2004-341515 (a monolayer stretching method). In addition, as described in JP-A-51-069644, JP-A-2000-338329, JP-A-2001-343521, WO 2010/100917, JP-A-2012-073563, and JP-A-2011-2816, there is exemplified a production method including a step of stretching a PVA-based resin layer and a stretching resin base material in the state of a laminate and a step of dyeing the laminate. According to this production method, even when the PVA-based resin layer is thin, such resin layer can be stretched without inconveniences such as breakage due to stretching because the resin layer is supported by the stretching resin base material.

As the production method including a step of stretching in the state of a laminate and a step of dyeing the laminate, an air stretching (dry stretching) method as described in JP-A-51-069644, JP-A-2000-338329, or JP-A-2001-343521 is exemplified. From the viewpoint of being able to stretching to a high drawing ratio and improve the polarization performance, a production method including a step of stretching in an aqueous boric acid solution as described in WO 2010/100917 A and JP-A-2012-073563 is preferable, and a production method (two-step stretching method) including a step of performing an auxiliary in-air stretching before stretching in an aqueous boric acid solution as described in JP-A-2012-073563 is particularly preferable. In addition, as described in JP-A-2011-2816, a method of stretching a PVA-based resin layer and a stretching resin base material in a laminate state, excessively dyeing the PVA-based resin layer, and then decoloring the dyed resin layer (excess dyeing decolorization method) is also preferable. The polarizer used in the present invention can be a polarizer made of a polyvinyl alcohol-based resin in which iodine is aligned as described above, and such a polarizer can be obtained by stretching in a two-step stretching step including an auxiliary in-air stretching and a stretching in an aqueous boric acid solution. The polarizer used in the present invention is made of the polyvinyl alcohol-based resin in which iodine is aligned as described above and can be produced by excessively dyeing the laminate of the stretched PVA-based resin layer and the stretching resin base material and then decoloring the dyed laminate.

The thickness of the polarizer used in the present invention is preferably 12 μm or less, more preferably 9 μm or less, even more preferably 1 to 8 μm, particularly preferably 3 to 6 μm. A preferred embodiment is within the above range without hindering the bending.

### <Retardation Film>

As the retardation film that can be used in the present invention, one obtained by stretching a polymer film or one obtained by aligning and fixing a liquid crystal material can be used. In the present specification, the retardation film means a film having birefringence in the plane and/or thickness direction.

Examples of the retardation film may include an anti-reflection retardation film (see paragraphs [0221], [0222], and [0228] in JP-A-2012-133303), a viewing-angle compensating retardation film (see paragraphs [0225] and [0226] in JP-A-2012-133303), and a viewing-angle compensating obliquely-aligned retardation film (see paragraph [0227] in JP-A-2012-133303).

Any known retardation film substantially having any of the functions described above can be used irrespective of, for example, the retardation value, the arrangement angle, the three-dimensional birefringence index, whether or not a single layer or a multilayer, and other factors.

The absolute value of a photoelastic coefficient C (m²/N) of the retardation film at 23° C. ranges from 2×10⁻¹² to 100×10⁻¹² (m²/N), preferably from 2×10⁻¹² to 50×10⁻¹² (m²/N). It prevents a change in the retardation value caused by force acting on the retardation film due to contraction stress in the polarizer, heat generated by a display panel, and a surrounding environment (humidity resistance, heat resistance). As a result, a display panel device having satisfactory display uniformity can be provided. The absolute value of the photoelastic coefficient C of the retardation film preferably ranges from 3×10⁻¹² to 45×10⁻¹², particularly preferably from 10×10⁻¹² to 40×10⁻¹². Setting C to fall within any of the ranges described above allows reduction in the change and unevenness in the retardation value resulting from force acting on the retardation film. Further, a tradeoff relationship between the photoelastic coefficient and Δn tends to occur, and the photoelastic coefficient that falls within any of the ranges described above allows display quality to be maintained with no decrease in degree of retardation manifestation.

In one embodiment, the retardation film according to the present invention is produced by stretching a polymer film to align therein.

As a method for stretching the polymer film described above, any appropriate stretching method may be employed in accordance with the purpose. Examples of the stretching method suitable for the present invention may include a lateral uniaxial stretching method, a longitudinal/lateral simultaneous biaxial stretching method, and a longitudinal/lateral successive biaxial stretching method. Examples of stretching means used may include a tenter stretcher, a biaxial stretcher, or any other appropriate stretcher. The stretcher preferably includes temperature control means. When a film is stretched while heated, the internal temperature in the stretcher may be continuously changed or may be continuously changed. The stretching step may be carried out once or may be divided into two or more steps. The stretching direction is preferably a film width direction (TD direction) or an oblique direction.

In the oblique stretching, an oblique stretching process is continuously carried out as follows: an unstretched resin film is stretched in a direction inclining with respect to the width direction of the film by an angle that falls within the specific range described above with the film fed in the longitudinal direction. An elongated retardation film can thus be so produced that the angle between the width direction and the slow axis direction of the film (alignment angle θ) falls within the specific range described above.

The method for performing oblique stretching is not limited to a specific method and may be any method that allows an unstretched resin film to be continuously stretched in a direction inclining with respect to the width direction of the film by an angle that falls within the specific range described above to form a slow axis in the direction inclining with respect to the width direction of the film by the angle that falls within the specific range described above. An appropriate stretching method may be selected from conventionally known stretching methods, for example, in JP-A-2005-319660, JP-A-2007-30466, JP-A-2014-194482, JP-A-2014-199483, and JP-A-2014-199483.

Further, as another embodiment, a retardation film formed as follows may be used: polycycloolefin films, polycarbonate films, or any other films are bonded in sheet form to each other with an acrylic pressure-sensitive adhesive in such a way that the angle between the absorption axis of a polarizing film and the slow axis of a half-wavelength plate is 15° and the angle between the absorption axis of the polarizing film and the slow axis of a quarter-wavelength plate is 75°.

In another embodiment, the usable retardation film may be a laminate of retardation layers produced by aligning and fixing a liquid crystal material. Each of the retardation layers may be an alignment fixed layer of a liquid crystal compound. Since use of a liquid crystal compound allows the difference between nx and ny of the resultant retardation layer to significantly increase as compared with the difference in a non-liquid-crystal material, the thickness of a retardation layer for providing desired in-plane retardation difference can be significantly reduced. As a result, the thickness of the circularly polarizing film (eventually, thickness of a flexible image display device) can be further reduced. In the present specification, the “alignment fixed layer” refers to a layer in which liquid crystal compound are aligned in a predetermined direction and the alignment state is fixed. In the present embodiment, a representative example of the aligned liquid crystal compound is so aligned as to be aligned with the slow axis direction of the retardation layer (homogeneous alignment). An example of the liquid crystal compound may include a liquid crystal compound having a nematic liquid crystal phase (nematic liquid crystal). As the liquid crystal compound, for example, a liquid crystal polymer or a liquid crystal monomer can be used. The mechanism in accordance with which the liquid crystal property of the liquid crystal compound manifests may be the lyotropic or thermotropic mechanism. A liquid crystal polymer and a liquid crystal monomer may be used alone or in combination.

The alignment fixed layer of the liquid crystal compound may be formed by performing an alignment treatment on a surface of a predetermined base material, coating the surface with a coating liquid containing a liquid crystal compound to align the liquid crystal compound in the direction corresponding to the alignment treatment, and fixing the alignment state. In one embodiment, the base material may be any appropriate resin film, and the aligned and fixed layer formed on the base material may be transferred onto a surface of the polarizer. At this point, the alignment fixed layer is so disposed that the angle between the absorption axis of the polarizer and the slow axis of the liquid crystal alignment fixed layer is 15°. The retardation of the liquid crystal alignment fixed layer is λ/2 (about 270 nm) of the wavelength of 550 nm. Further, a liquid crystal alignment fixed layer having a retardation of λ/4 (about 140 nm) of the wavelength of 550 nm is formed on the transferable base material in the same manner described above and so layered on the side of the half-wavelength plate of the laminate of the polarizer and the half-wavelength plate that the angle between the absorption axis of the polarizer and the slow axis of the quarter-wavelength plate is 75°.

As the alignment treatment described above, any appropriate alignment treatment may be employed. Specifically, a mechanical alignment treatment, a physical alignment treatment, and a chemical alignment treatment may be listed as candidates of the alignment treatment. Specific examples of the mechanical alignment treatment may include a rubbing treatment and a stretching treatment. Specific examples of the physical alignment treatment may include a magnetic field alignment treatment and an electric field alignment treatment. Specific examples of the chemical alignment treatment may include an oblique evaporation method and an optical alignment treatment. Treatment conditions under which each of the alignment treatments is performed may be any appropriate conditions in accordance with the purpose.

The thickness of the retardation film used in the present invention is preferably 20 μm or less, more preferably 10 μm or less, even more preferably 1 to 9 μm, particularly preferably 3 to 8 μm. A preferred embodiment is within the above range without hindering the bending.

### <Protective Film>

The protective film of a transparent resin material (also referred to as a transparent protective film) used in the present invention may be a cycloolefin-based resin such as a norbornene-based resin, an olefin-based resin such as polyethylene and polypropylene, a polyester-based resin, a (meth)acrylic resin or the like.

A thickness of the protective film used in the present invention ranges preferably from 5 to 60 μm, more preferably from 10 to 40 μm, even more preferably 10 to 30 μm, and a surface treatment layer such as an anti-glare layer or an antireflection layer, may be provided as appropriate. A preferred embodiment is within the above range without hindering the bending.

### [Pressure-Sensitive Adhesive Layer]

The pressure-sensitive adhesive layer for a flexible image display device of the present invention (sometimes simply referred to as a pressure-sensitive adhesive layer) is preferably disposed on the side opposite to the surface in contact with the polarizer with respect to the protective film.

In the pressure-sensitive adhesive layer for a flexible image display device of the present invention, any pressure-sensitive adhesive composition containing a (meth)acrylic polymer can be used without particular limitation as long as the weight average molecular weight (Mw) of the polymer is 1,000,000 to 2,500,000 and the glass transition temperature (Tg) is 0° C. or less. A combination of two or more pressure-sensitive adhesives selected from acrylic pressure-sensitive adhesives, rubber-based pressure-sensitive adhesives, vinyl alkyl ether-based pressure-sensitive adhesives, silicone-based pressure-sensitive adhesives, polyester-based pressure-sensitive adhesives, polyamide-based pressure-sensitive adhesives, urethane-based pressure-sensitive adhesives, fluorine-based pressure-sensitive adhesives, epoxy-based pressure-sensitive adhesives, polyether-based pressure-sensitive adhesives, and the like may be used. However, from the viewpoints of transparency, processability, durability, adhesiveness, bending resistance, etc., it is preferable to use an acrylic pressure-sensitive adhesives alone.

### <(Meth)acrylic Polymer>

The pressure-sensitive adhesive layer for a flexible image display device of the present invention is characterized by being formed from a pressure-sensitive adhesive composition containing a (meth)acrylic polymer. When an acrylic pressure-sensitive adhesives is used as the pressure-sensitive adhesive composition, the composition preferably contains a (meth)acrylic monomer having a linear or branched alkyl group of 1 to 24 carbon atoms as a monomer unit. By using the (meth)acrylic monomer having the linear or branched alkyl group of 1 to 24 carbon atoms, a pressure-sensitive adhesive layer having excellent bendability can be obtained. In the present invention, the term “(meth)acrylic polymer” refers to an acrylic polymer and/or a methacrylic polymer, and the term “(meth)acrylate” refers to an acrylate and/or a methacrylate.

Specific examples of the (meth)acrylic monomer having a linear or branched alkyl group of 1 to 24 carbon atoms forming the main skeleton of the (meth)acrylic polymer include methyl (meth)acrylate, ethyl (meth)acrylate, n-butyl (meth)acrylate, s-butyl (meth)acrylate, t-butyl (meth)acrylate, isobutyl (meth)acrylate, n-pentyl (meth)acrylate, isopentyl (meth)acrylate, n-hexyl (meth)acrylate, isohexyl (meth)acrylate, isoheptyl (meth)acrylate, 2-ethylhexyl (meth)acrylate, n-octyl (meth)acrylate, isooctyl (meth)acrylate, n-nonyl (meth)acrylate, isononyl (meth)acrylate, n-decyl (meth)acrylate, isodecyl (meth)acrylate, n-dodecyl (meth)acrylate, n-tridecyl (meth)acrylate, n-tetradecyl (meth)acrylate, etc. Among them, a monomer having a low glass transition temperature (Tg) generally becomes a viscoelastic substance even in a lower temperature range. Thus, from the viewpoint of bendability, a (meth)acrylic monomer having a linear or branched alkyl group of 4 to 8 carbon atoms is preferable. As the (meth)acrylic monomer, one or two or more kinds thereof can be used.

The (meth)acrylic monomer having a linear or branched alkyl group of 1 to 24 carbon atoms is a main component in all the monomers forming the (meth)acrylic polymer. Here, as the main component, the total amount of (meth)acrylic monomer having a linear or branched alkyl group of 1 to 24 carbon atoms in all the monomers constituting the (meth)acrylic polymer is preferably 70 to 100% by weight, more preferably from 80 to 99.9% by weight, even more preferably from 85 to 99.9% by weight, particularly preferably from 90 to 99.8% by weight.

As the monomer unit forming the (meth)acrylic polymer, it is preferable to contain a (meth)acrylic polymer containing a hydroxyl group-containing monomer having a reactive functional group. By using the hydroxyl group-containing monomer, a pressure-sensitive adhesive layer excellent in adhesiveness and bendability can be obtained. The hydroxyl group-containing monomer contains a hydroxyl group in its structure and is a compound containing a polymerizable unsaturated double bond such as a (meth)acryloyl group or a vinyl group.

Specific examples of the hydroxyl group-containing monomer include hydroxyalkyl (meth)acrylates such as 2-hydroxyethyl (meth)acrylate, 3-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate, and (4-hydroxymethylcyclohexyl)-methyl acrylate. Among the hydroxyl group-containing monomers, 2-hydroxyethyl (meth)acrylate and 4-hydroxybutyl (meth)acrylate are preferable from the viewpoint of durability and adhesiveness. One or two or more kinds of the hydroxyl group-containing monomers may be used.

In addition, as the monomer unit forming the (meth)acrylic polymer, it is possible to contain a monomer having a reactive functional group, such as a carboxyl group-containing monomer, an amino group-containing monomer, and an amide group-containing monomer. It is preferable to use these monomers from the viewpoint of adhesiveness under moist heat environment.

As the monomer unit forming the (meth)acrylic polymer, a (meth)acrylic polymer containing a carboxyl group-containing monomer having a reactive functional group can be contained. By using the carboxyl group-containing monomer, it is possible to obtain a pressure-sensitive adhesive layer having excellent adhesiveness under a moist heat environment. The carboxyl group-containing monomer is a compound containing a carboxyl group as well as a polymerizable unsaturated double bond such as a (meth)acryloyl group, a vinyl group or the like in its structure.

Specific examples of the carboxyl group-containing monomer include (meth)acrylic acid, carboxyethyl (meth)acrylate, carboxypentyl (meth)acrylate, itaconic acid, maleic acid, fumaric acid, crotonic acid, and the like.

The monomer unit forming the (meth)acrylic polymer can include a (meth)acrylic polymer containing an amino group-containing monomer having a reactive functional group. By using the amino group-containing monomer, it is possible to obtain a pressure-sensitive adhesive layer having excellent adhesiveness under a moist heat environment. The amino group-containing monomer is a compound containing an amino group as well as a polymerizable unsaturated double bond such as a (meth)acryloyl group, a vinyl group or the like in its structure.

Specific examples of the amino group-containing monomer include N,N-dimethylaminoethyl (meth)acrylate, N,N-dimethylaminopropyl (meth)acrylate, and the like.

The monomer unit forming the (meth)acrylic polymer can include an amide group-containing monomer having a reactive functional group. By using the amide group-containing monomer, a pressure-sensitive adhesive layer having excellent adhesiveness can be obtained. The amide group-containing monomer is a compound containing an amide group and a polymerizable unsaturated double bond such as a (meth)acryloyl group and a vinyl group in its structure.

Specific examples of the amide group-containing monomer include acrylamide-based monomers such as (meth)acrylamide, N,N-dimethyl (meth)acrylamide, N,N-diethyl (meth)acrylamide, N-isopropylacrylamide, N-methyl (meth)acrylamide, N-butyl (meth)acrylamide, N-hexyl (meth)acrylamide, N-methylol (meth)acrylamide, N-methylol-N-propane (meth)acrylamide, aminomethyl (meth)acrylamide, aminoethyl (meth)acrylamide, mercaptomethyl (meth)acrylamide, and mercaptoethyl (meth)acrylamide; N-acryloyl heterocyclic monomers such as N-(meth)acryloyl morpholine, N-(meth)acryloyl piperidine, and N-(meth)acryloyl pyrrolidine; N-vinyl-containing lactam monomers such as N-vinylpyrrolidone and N-vinyl-ε-caprolactam; and the like.

As a monomer unit forming the (meth)acrylic polymer, the blending ratio (total amount) of the monomer having a reactive functional group is preferably 20% by weight or less, more preferably 10% by weight or less, even more preferably 0.01 to 8% by weight, particularly preferably 0.01 to 5% by weight, most preferably 0.05 to 3% by weight in the total monomers forming the (meth)acrylic polymer. When such blending ratio exceeds 20% by weight, the number of crosslinking points increases and the flexibility of the pressure-sensitive adhesive (layer) is lost, so that the stress relaxation property tends to be poor.

As the monomer unit forming the (meth)acrylic polymer, in addition to the monomer having a reactive functional group, other copolymerizable monomers can be introduced as long as the effect of the present invention is not impaired. The blending ratio is not particularly limited but is preferably 30% by weight or less with respect to all the monomers forming the (meth)acrylic polymer, and it is more preferable not to contain other copolymerizable monomers. When the blending ratio exceeds 30% by weight, in particular when a monomer other than the (meth)acrylic monomer is used, the reaction point with the film tends to be small and the adhesion tends to decrease.

In the present invention, when the (meth)acrylic polymer is used, such polymer usually has a weight average molecular weight (Mw) in the range of 1,000,000 to 2,500,000. In consideration of durability, particularly heat resistance and bendability, the weight average molecular weight is preferably from 1,200,000 to 2,200,000, more preferably from 1,400,000 to 2,000,000. When the weight average molecular weight is smaller than 1,000,000, at the time of crosslinking the polymer chains with each other in order to ensure durability, the number of crosslinking points is increased to lose the flexibility of the pressure-sensitive adhesive (layer), compared with those having a weight average molecular weight of 1,000,000 or more, and as a result, the dimensional change of the outer bend side (convex side) and the inner bend side (concave side) occurring between the films at the time of bending cannot be alleviated, and the film tends to break easily. In addition, when the weight average molecular weight exceeds 2,500,000, a large amount of a diluting solvent is required for adjusting the viscosity for coating, which undesirably leads to an increase in cost, and since the entanglement of the polymer chains of the resulting (meth)acrylic polymer becomes complicated, flexibility is inferior and breakage of the film is likely to occur at the time of bending. The weight average molecular weight (Mw) is a value calculated in terms of polystyrene as measured by GPC (gel permeation chromatography).

Such a (meth)acrylic polymer may be produced by a method selected appropriately from known production methods such as solution polymerization, bulk polymerization, emulsion polymerization and various radical polymerizations. The resultant (meth)acrylic polymer may be any one of random copolymers, block copolymers, graft copolymers, and the like.

In the solution polymerization, as a polymerization solvent, for example, ethyl acetate, toluene, or the like is used. In a specific example of the solution polymerization, a reaction is performed in the presence of a polymerization initiator in an inert gas, such as nitrogen, ordinarily under the reaction conditions of a temperature of about 50 to 70° C. and a period of about 5 to 30 hours.

A polymerization initiator, a chain transfer agent, an emulsifier and others that are used in the radical polymerizations are not particularly limited and may be used after appropriate selection. The weight average molecular weight of the (meth)acrylic polymer is controllable in accordance with the respective use amounts of the polymerization initiator and the chain transfer agent, and the reaction conditions. The amount of use thereof is appropriately adjusted according to the kind of these substances.

Examples of the polymerization initiator include, but are not limited to, azo initiators such as 2,2′-azobisisobutylonitrile, 2,2′-azobis(2-amidinopropane) dihydrochloride, 2,2′-azobis[2-(5-methyl-2-imidazolin-2-yl)propane] dihydrochloride, 2,2′-azobis(2-methylpropionamidine) disulfate, 2,2′-azobis(N,N′-dimethyleneisobutylamidine), and 2,2′-azobis[N-(2-carboxyethyl)-2-methylpropionamidine] hydrate (VA-057, manufactured by Wako Pure Chemical Industries, Ltd.); persulfates such as potassium persulfate and ammonium persulfate; peroxide-based initiators such as di(2-ethylhexyl) peroxydicarbonate, di(4-tert-butylcyclohexyl) peroxydicarbonate, di-sec-butyl peroxydicarbonate, tert-butyl peroxyneodecanoate, tert-hexyl peroxypivalate, tert-butyl peroxypivalate, dilauroyl peroxide, di-n-octanoyl peroxide, 1,1,3,3-tetramethylbutyl peroxy-2-ethylhexanoate, di(4-methylbenzoyl) peroxide, dibenzoyl peroxide, tert-butyl peroxyisobutylate, 1,1-di(tert-hexylperoxy) cyclohexane, tert-butyl hydroperoxide, and hydrogen peroxide; and redox system initiators of a combination of a peroxide and a reducing agent, such as a combination of a persulfate and sodium hydrogen sulfite and a combination of a peroxide and sodium ascorbate.

One of the above polymerization initiators may be used alone, or two or more thereof may be used in a mixture. The total content of the polymerization initiator is preferably from about 0.005 to 1 part by weight, more preferably from about 0.02 to about 0.5 parts by weight, per 100 parts by weight of all the monomers forming the (meth)acrylic polymer.

In the case of using a chain transfer agent, an emulsifier used for emulsion polymerization, or a reactive emulsifier, conventionally known ones can be appropriately used. In addition, these addition amounts can be appropriately determined within a range not to impair the effect of the present invention.

### <Crosslinking Agent>

The pressure-sensitive adhesive composition of the present invention may contain a crosslinking agent. An organic crosslinking agent or a polyfunctional metal chelate may be used as the crosslinking agent. Examples of the organic crosslinking agent include an isocyanate-based crosslinking agent, a peroxide-based crosslinking agent, an epoxy-based crosslinking agent, an imine-based crosslinking agent, and the like. The polyfunctional metal chelate may include those in which a polyvalent metal is covalently or coordinately bonded to an organic compound. Examples of the polyvalent metal atom include Al, Cr, Zr, Co, Cu, Fe, Ni, V, Zn, In, Ca, Mg, Mn, Y, Ce, Sr, Ba, Mo, La, Sn, and Ti. Examples of the atom in the organic compound that is covalently or coordinately bonded include an oxygen atom and the like. Examples of the organic compound include alkyl esters, alcohol compounds, carboxylic acid compounds, ether compounds, ketone compounds, and the like. Among them, an isocyanate-based crosslinking agent (particularly, a trifunctional isocyanate-based crosslinking agent) is preferable from the viewpoint of durability, and a peroxide-based crosslinking agent and an isocyanate-based crosslinking agent (in particular, a bifunctional isocyanate-based crosslinking agent) is preferable in terms of bendability. Both the peroxide-based crosslinking agent and the bifunctional isocyanate-based crosslinking agent form a flexible two-dimensional crosslinking, whereas the trifunctional isocyanate-based crosslinking agent forms a stronger three-dimensional crosslinking. When bending, two-dimensional crosslinking, which is a more flexible crosslinking, is advantageous. However, since two-dimensional crosslinking alone is poor in durability and peeling is likely to occur, hybrid crosslinking between two-dimensional crosslinking and three-dimensional crosslinking is favorable, so that a trifunctional isocyanate-based crosslinking agent and a peroxide-based crosslinking agent or a bifunctional isocyanate-based crosslinking agent are preferably used in combination.

The amount of the crosslinking agent to be used is preferably 0.01 to 5 parts by weight, more preferably 0.03 to 2 parts by weight, and more preferably less than 0.03 to 1 part by weight, per 100 parts by weight of the (meth)acrylic polymer. Within the above range, a preferred embodiment excellent in bending resistance is obtained.

### <Other Additives>

Further, the pressure-sensitive adhesive composition of the present invention may contain any other known additives, including, for example, various silane coupling agents, polyether compounds such as polyalkylene glycol (e.g. polypropylene glycol etc.), powder such as coloring agents and pigments, dyes, surfactants, plasticizers, tackifiers, surface lubricants, leveling agents, softeners, antioxidants, anti-ageing agents, light stabilizers, ultraviolet absorbers, polymerization inhibitors, antistatic agents (alkali metal salt or ionic liquid which are an ionic compound, etc.), inorganic or organic fillers, metal powder, particle- or foil-shaped materials, and the like, and such additives can be appropriately added depending on the intended use. In addition, a redox system including a reducing agent to be added may also be used in the controllable range.

In the case where the pressure-sensitive adhesive layer for a flexible image display device further has a pressure-sensitive adhesive layer, these pressure-sensitive adhesive layers may have the same composition (same pressure-sensitive adhesive composition), have the same characteristics, or have different characteristics, but are not particularly limited. In the case of having a plurality of pressure-sensitive adhesive layers, it is required that the storage elastic modulus G′ at 25° C. of the pressure-sensitive adhesive layer on the outermost surface on the convex side when the laminate is folded is substantially the same as or smaller than the storage elastic modulus G′ at 25° C. of the other adhesive layer. From the viewpoints of workability, economic efficiency, and bendability, it is preferable that all the pressure-sensitive adhesive layers are pressure-sensitive adhesive layers having substantially the same composition and the same characteristics. The term “substantially the same” means that the difference in storage elastic modulus (G′) between the pressure-sensitive adhesive layers is within the range of ±15%, preferably within the range of ±10%, with respect to the average value of the storage elastic modulus (G′) of a plurality of pressure-sensitive adhesive layers.

### <Formation of Pressure-Sensitive Adhesive Layer>

The pressure-sensitive adhesive layer in the present invention is preferably formed from the pressure-sensitive adhesive composition. For example, the pressure-sensitive adhesive layer may be formed by a method including applying the pressure-sensitive adhesive composition to a release-treated separator or the like, removing the polymerization solvent and the like by drying to form a pressure-sensitive adhesive layer, or by a method including applying the pressure-sensitive adhesive composition to a polarizing film or the like, and removing the polymerization solvent and the like by drying to form a pressure-sensitive adhesive layer on the polarizing film or the like. In applying the pressure-sensitive adhesive composition, one or more kinds of solvents other than the polymerization solvent may be newly added as needed.

A silicone release liner is preferably used as the release-treated separator. When the pressure-sensitive adhesive composition of the present invention is applied to such a liner and dried to form a pressure-sensitive adhesive layer, any appropriate drying method may be suitably adopted depending on the purpose. A method of drying under heating is preferably used. The heat drying temperature is preferably from 40° C. to 200° C., more preferably from 50° C. to 180° C., particularly preferably from 70° C. to 170° C. When the heating temperature is set in the above range, a pressure-sensitive adhesive layer having good adhesive properties can be obtained.

Any suitable drying time may be used as appropriate. The drying time is preferably from 5 seconds to 20 minutes, more preferably from 5 seconds to 10 minutes, particularly preferably from 10 seconds to 5 minutes.

As a coating method of the pressure-sensitive adhesive composition, various methods may be used. Specific examples of such methods include a roll coating method, a kiss roll coating method, a gravure coating method, a reverse coating method, a roll brush coating method, a spray coating method, a dip roll coating method, a bar coating method, a knife coating method, an air knife coating method, a curtain coating method, a lip coating method, and an extrusion coating method with a die coater or the like.

The thickness of the pressure-sensitive adhesive layer for a flexible image display device of the present invention is preferably 5 to 150 μm, more preferably 15 to 100 μm. The pressure-sensitive adhesive layer may be a single layer or may have a laminated structure. Within the above range, such a thickness is a preferred embodiment in terms of not inhibiting bending and also in terms of adhesiveness (retention resistance). If the thickness of the pressure-sensitive adhesive layer exceeds 150 μm, peeling may occur because polymer chains in the pressure-sensitive adhesive layer are easy to move and deteriorate drastically during repetitive bending. In the case of less than 5 μm, the stress at the time of bending cannot be relaxed, and breakage may occur. Further, in the case of having a plurality of pressure-sensitive adhesive layers, all the pressure-sensitive adhesive layers are preferably within the above-mentioned range.

The glass transition temperature (Tg) of the pressure-sensitive adhesive layer for a flexible image display device of the present invention is 0° C. or less, preferably −20° C. or less, more preferably −25° C. or less. The lower limit of Tg is preferably −50° C. or more, more preferably −45° C. or more. When the Tg of the pressure-sensitive adhesive layer is in such a range, the pressure-sensitive adhesive layer hardly becomes hard at the time of bending under a low-temperature environment and peeling of the pressure-sensitive adhesive layer and breakage of the polarizer can be suppressed because the stress relaxation property is excellent. Thus, it is possible to realize a bendable or foldable flexible image display device.

The storage elastic modulus (G′) of the pressure-sensitive adhesive layer for a flexible image display device of the present invention at 25° C. is preferably 1.0 MPa or less, more preferably 0.8 MPa or less, even more preferably 0.3 MPa or less. Further, at −20° C., the storage elastic modulus is preferably 1.5 MPa or less, more preferably 1.0 MPa or less, even more preferably 0.5 MPa or less. When the storage elastic modulus of the pressure-sensitive adhesive layer is in such a range, it is difficult for the pressure-sensitive adhesive layer to become hard, and such pressure-sensitive adhesive layer is superior in stress relaxation property and excellent in bending resistance, so that it is possible to realize a bendable or foldable flexible image display device.

The adhesive strength of the pressure-sensitive adhesive layer for a flexible image display device of the present invention to a polarizing film is preferably 5 to 40 N/25 mm, more preferably 8 to 38 N/25 mm, and even more preferably 10 to 36 N/25 mm. When the adhesive strength of the pressure-sensitive adhesive layer is within such a range, it is possible to realize a flexible image display device which is excellent in adhesiveness and does not peel off against repeated bending and is bendable or foldable. Regarding the adhesive strength, whatever the polarizing film is, it is a preferred embodiment to be included in the above range. As the adhesive strength to the polarizing film, for example, the adhesive strength (N/25 mm) at the time of peeling at a peeling angle of 180° and a peeling rate of 300 mm/min using a tensile tester (Autograph SHIMAZU AG-1 10 KN) can be measured.

The total light transmittance (according to JIS K7136) in the visible light wavelength region of the pressure-sensitive adhesive layer for a flexible image display device of the present invention is preferably 85% or more, more preferably 90% or more.

The haze (according to JIS K7136) of the pressure-sensitive adhesive layer for a flexible image display device of the present invention is preferably 3.0% or less, more preferably 2.0% or less.

Incidentally, the total light transmittance and the haze can be measured using, for example, a haze meter (trade name “HM-150”, manufactured by Murakami Color Research Laboratory).

### [Transparent Conductive Layer]

For the purpose of imparting a touch sensor function and the like to the laminate for a flexible image display device of the present invention, it is preferable to provide a transparent conductive layer with an interposed pressure-sensitive adhesive layer of the present invention. A member having a transparent conductive layer is not particularly limited and known materials can be used. Examples of such a member include a member having a transparent conductive layer on a transparent base material such as a transparent film or the like and a member having a transparent conductive layer and a liquid crystal cell.

The transparent base material may be of any type having transparency, and examples thereof include a base material (for example, a sheet-like, film-like, or plate-like base material) made of a resin film or the like. The thickness of the transparent base material is not particularly limited, but is preferably about 10 to 200 μm, more preferably about 15 to 150 μm.

The resin film may be made of any material, such as any of various plastic materials having transparency. Examples of such materials include polyester-based resins such as polyethylene terephthalate and polyethylene naphthalate, acetate-based resins, polyethersulfone-based resins, polycarbonate-based resins, polyamide-based resins, polyimide-based resins, polyolefin-based resins, (meth)acrylic resins, polyvinyl chloride-based resins, polyvinylidene chloride-based resins, polystyrene-based resins, polyvinyl alcohol-based resins, polyarylate-based resins, and polyphenylene sulfide-based resins. Among them, polyester-based resins, polyimide-based resins, and polyethersulfone-based resins are particularly preferred.

The surface of the transparent base material may be previously subjected to sputtering, corona discharge treatment, flame treatment, ultraviolet irradiation, electron beam irradiation, chemical treatment, etching treatment such as oxidation, or undercoating treatment so that the transparent base material can have improved adhesiveness to the transparent conductive layer formed thereon. Before the transparent conductive layer is formed, if necessary, the transparent base material may be subjected to solvent washing or ultrasonic washing for removal of dust and cleaning.

Examples of the material used to form the transparent conductive layer include, but not limited to, metal oxides of at least a metal selected from the group consisting of indium, tin, zinc, gallium, antimony, titanium, silicon, zirconium, magnesium, aluminum, gold, silver, copper, palladium, and tungsten. If necessary, the metal oxides may be doped with any metal from the group shown above. For example, tin oxide-doped indium oxide (ITO) and antimony-doped tin oxide are preferably used, and in particular, ITO is preferably used. ITO preferably includes 80 to 99% by weight of indium oxide and 1 to 20% by weight of tin oxide.

The ITO may be crystalline or amorphous. The crystalline ITO can be obtained by high-temperature sputtering or further heating an amorphous ITO.

The thickness of the transparent conductive layer of the present invention is preferably 0.005 to 10 μm, more preferably 0.01 to 3 μm, even more preferably 0.01 to 1 μm. When the thickness of the transparent conductive layer is less than 0.005 μm, the transparent conductive layer tends to be more variable in electric resistance. On the other hand, the transparent conductive layer with a thickness of more than 10 μm may be produced with lower productivity at higher cost and tend to have a lower level of optical properties.

The total light transmittance of the transparent conductive layer of the present invention is preferably 80% or more, more preferably 85% or more, even more preferably 90% or more.

The density of the transparent conductive layer of the present invention is preferably 1.0 to 10.5 g/cm³, more preferably 1.3 to 3.0 g/cm³.

The surface resistance value of the transparent conductive layer of the present invention is preferably 0.1 to 1000Ω/□, more preferably 0.5 to 500Ω/□, even more preferably 1 to 250Ω/□.

The method for forming the transparent conductive layer is not particularly limited, and conventionally known methods can be adopted. Specifically, for example, a vacuum deposition method, a sputtering method, and an ion plating method can be exemplified. In addition, an appropriate method can be adopted according to the required film thickness.

In addition, an undercoat layer, an oligomer prevention layer, and the like can be provided between the transparent conductive layer and the transparent base material, if necessary.

The transparent conductive layer forms a touch sensor and is required to be configured to be bendable.

In addition, the transparent conductive layer can be suitably applied to a liquid crystal display device having a built-in in-cell or on-cell touch sensor as a case of being used for a flexible image display device, and in particular, a touch sensor may be built in (even incorporated in) an organic EL display panel.

### [Conductive Layer (Antistatic Layer)]

Further, the laminate for a flexible image display device of the present invention may have a layer having conductivity (a conductive layer, an antistatic layer). Since the laminate for a flexible image display device has a bending function and has a very thin thickness structure, such a laminate is highly responsive to feeble static electricity generated in a manufacturing process or the like and is easily damaged, but by providing a conductive layer in the laminate, the load due to static electricity in the manufacturing process and the like is largely reduced, which is a preferable embodiment.

In addition, it is one of the major features for the flexible image display device including the laminate to have a bending function, but in the case of continuous bending, static electricity may be generated due to shrinkage between the films (base materials) at the bent portion. Therefore, when conductivity is imparted to the laminated body, generated static electricity can be promptly removed, and damage caused by static electricity of the image display device can be reduced, which is a preferable embodiment.

Further, the conductive layer may be an undercoat layer having a conductive function, a pressure-sensitive adhesive containing a conductive component, or a surface treatment layer containing a conductive component. For example, a method of forming a conductive layer between a polarizing film and a pressure-sensitive adhesive layer by using an antistatic composition containing a binder and a conductive polymer such as polythiophene can be employed. Further, a pressure-sensitive adhesive containing an ionic compound which is an antistatic agent can also be used. The conductive layer preferably has one or more layers and may contain two or more layers.

### [Flexible Image Display Device]

The flexible image display device of the present invention includes the laminate for a flexible image display device and an organic EL display panel configured to be foldable, wherein the laminate for a flexible image display device is disposed on a viewing side and configured to be foldable with respect to the organic EL display panel. The liquid crystal panel may be used instead of the organic EL display panel, and the window may be disposed on a viewing side with respect to the laminate for a flexible image display device.

The flexible image display device of the present invention can be suitably used as a flexible liquid crystal display device, an organic EL (electroluminescence) display device, a PDP (plasma display panel), and an electronic paper. Further, such a flexible image display device can be used irrespective of a touch panel or the like such as a resistive film type or a capacitive type.

As shown in FIG. 2, the flexible image display device of the present invention may also be used as an in-cell type flexible image display device in which a transparent conductive layer 6 forming a touch sensor is incorporated in an organic EL display panel 10.

### EXAMPLES

Several examples relating to the present invention will be described below, but the present invention is not intended to be limited to such specific examples. In addition, the numerical values in tables are blending amounts (addition amounts) and showed solid contents or solid fractions (weight basis). The contents of the formulation and the evaluation results are shown in Tables 1 to 4.

### Example 1

### [Polarizer]

An amorphous polyethylene terephthalate (hereinafter referred to as “PET”) (IPA-copolymerized PET) film (thickness: 100 μm) with 7 mol % of isophthalic acid unit was used as a thermoplastic resin base material, and a surface of the film was subjected to a corona treatment (58 W/m²/min). Further, a PVA (polymerization degree: 4200, saponification degree: 99.2%) added with 1 wt % of acetoacetyl-modified PVA (trade name: Gohsefimer Z200 (average polymerization degree: 1200, saponification degree: 98.5 mol %, acetoacetyl-modification degree: 5 mol %), manufactured by Nippon Synthetic Chemical Industry Co., Ltd.) was used to preliminarily prepare a coating solution consisting of an aqueous PVA solution containing 5.5 wt % of PVA-based resin. Then, the coating solution was applied onto a base material to allow a film thickness after drying to become 12 μm and subjected to hot-air drying under an atmosphere at 60° C. for 10 minutes to prepare a laminate in which a layer of the PVA-based resin is provided on the base material.

Then, this laminate was first subjected to free-end stretching in air (auxiliary in-air stretching) at 130° C. at a stretching ratio of 1.8 times to form a stretched laminate. Then, the stretched laminate was immersed in a boric acid insolubilizing aqueous solution having a temperature of 30° C. for 30 seconds to perform a step of insolubilizing a PVA layer in which PVA molecules are aligned and which is contained in the stretched laminate. The boric acid insolubilizing aqueous solution in this step was prepared to allow a boric acid to be contained in an amount of 3 weight parts with respect to 100 weight parts of water. The stretched laminate was subjected to dyeing to form a dyed laminate. The dyed laminate was prepared by immersing the stretched laminate in a dyeing solution containing iodine and potassium iodide and having a temperature of 30° C. for an arbitrary time, in such a manner that a single layer transmittance of a PVA layer making up a polarizer to be finally obtained falls with the range of 40 to 44%, thereby causing the PVA layer included in the stretched laminate to be dyed with iodine. In this step, the dyeing solution was prepared using water as a solvent to allow an iodine concentration and a potassium iodide concentration to fall with the range of 0.1 to 0.4% by weight, and the range of 0.7 to 2.8% by weight, respectively. A concentration ratio of iodine to potassium iodide was 1:7. Then a step of immersing the dyed laminate in a boric acid crosslinking aqueous solution at 30° C. for 60 seconds so as to subject PVA molecules in the PVA layer having iodine adsorbed therein to a cross-linking treatment was performed. The boric acid crosslinking aqueous solution in this step was set to contain boric acid in an amount of 3 weight parts with respect to 100 parts by weight of water and contain potassium iodide in an amount of 3 parts by weight with respect to 100 parts by weight of water.

Further, an obtained dyed laminate was stretched in an aqueous boric acid solution (stretching in an aqueous boric acid solution) at a stretching temperature of 70° C., at a stretching ratio of 3.05 times in the same direction as that during the previous in-air stretching to obtain an optical film laminate stretched at a final stretching ratio of 5.50 times. The optical film laminate was taken out of the aqueous boric acid solution, and a boric acid attaching on a surface of the PVA layer was washed with an aqueous solution containing 4 parts by weight of potassium iodide with respect to 100 pars by weight of water. The washed optical film laminate was dried through a drying step using hot air at 60° C. The polarizer included the obtained optical film laminate had a thickness of 5 μm.

### [Protective Film]

A protective film obtained by extruding a methacrylic resin pellet having a glutarimide ring unit to form a film shape and then stretching the film was used. This protective film had a thickness of 20 μm and was an acrylic film having a moisture permeability of 160 g/m².

Next, the polarizer and the protective film were bonded using an adhesive shown below to obtain a polarizing film.

As the adhesive (active energy ray-curable adhesive), each component was mixed according to the formulation table shown in Table 1 and stirred at 50° C. for 1 hour to prepare an adhesive (active energy ray-curable adhesive A). Numerical values in the table indicate weight % when the total amount of the composition is taken as 100% by weight. Each component used is as follows.

HEAA: Hydroxyethylacrylamide

M-220: ARONIX M-220, tripropylene glycol diacrylate) manufactured by Toagosei Co., Ltd.

ACMO: Acryloyl morpholine

AAEM: 2-Acetoacetoxyethyl methacrylate, manufactured by The Nippon Synthetic Chemical Industry Co., Ltd.

UP-1190: ARUFON UP-1190, manufactured by Toagosei Co., Ltd.

IRG 907: IRGACURE 907, 2-methyl-1-(4-methylthiophenyl)-2-morpholinopropan-1-one, manufactured by BASF

DETX-S: KAYACURE DETX-S, diethylthioxanthone, manufactured by Nippon Kayaku Co., Ltd.

TABLE 1

| | Adhesive |
|---|---|
| (wt %) | composition |
| HEAA | 11.4 |
| M-220 | 57.1 |
| ACMO | 11.4 |
| AAEM | 4.6 |
| UP-1190 | 11.4 |
| IRG 907 | 2.8 |
| DETX-S | 1.3 |

In examples and comparative examples using the adhesive, after the protective film and the polarizer were laminated with the interposed adhesive, the adhesive was cured by irradiation with ultraviolet light to form an adhesive layer. For irradiation with ultraviolet rays, a gallium-encapsulated metal halide lamp (trade name “Light HAMMER 10” manufactured by Fusion UV Systems, Inc., bulb: V bulb, peak illuminance: 1600 mW/cm², integrated irradiation amount: 1000/mJ/cm² (wavelength 380 to 440 nm)) was used.

### <Preparation of (Meth)acrylic Polymer A1>

A monomer mixture containing 99 parts by weight of butyl acrylate (BA) and 1 part by weight of 4-hydroxybutyl acrylate (HBA) was charged into a four-necked flask equipped with a stirring blade, a thermometer, a nitrogen gas inlet tube, and a condenser.

Further, 0.1 parts by weight of 2,2′-azobisisobutyronitrile as a polymerization initiator was charged into 100 parts by weight (solid content) of the monomer mixture together with ethyl acetate, and while gently stirring, nitrogen gas was introduced to carry out nitrogen substitution, and polymerization reaction was carried out for 7 hours while maintaining the liquid temperature in the flask at around 55° C. Thereafter, ethyl acetate was added to the obtained reaction solution to prepare a solution of a (meth)acrylic polymer A1 having a weight average molecular weight of 1,600,000, which was adjusted to have a solid content concentration of 30%.

<Preparation of Acrylic Pressure-sensitive adhesive Composition>

An isocyanate-based crosslinking agent (0.1 parts by weight, trade name: TAKENATE D110N, trimethylolpropane xylylene diisocyanate, manufactured by Mitsui Chemicals, Inc.), 0.3 parts by weight of a peroxide-based crosslinking agent, benzoyl peroxide (trade name: NYPER BMT, manufactured by NOF Corporation), and 0.08 parts by weight of a silane coupling agent (trade name: KBM 403, manufactured by Shin-Etsu Chemical Co., Ltd.), an acrylic pressure-sensitive adhesive composition were blended per 100 parts by weight of the solid content of the resulting (meth)acrylic polymer A1 solution, thereby to prepare an acrylic pressure-sensitive adhesive composition.

### <Pressure-Sensitive Adhesive Layer Attached Laminate>

Using a fountain coater, the acrylic pressure-sensitive adhesive composition was uniformly applied to the surface of a polyethylene terephthalate film (PET film, separator) having a thickness of 38 μm treated with a silicone-based releasing agent, and dried in an air-circulated constant temperature oven at 155° C. for 2 minutes to form a pressure-sensitive adhesive layer having a thickness of 25 μm on the surface of the base material.

Then, the separator having the pressure-sensitive adhesive layer 1 formed thereon was transferred to the protective film side (corona-treated side) of the obtained polarizing film to prepare a pressure-sensitive adhesive layer attached laminate.

Then, as shown in FIG. 3, a PET film having a thickness of 25 μm (transparent base material, DIAFOIL, manufactured by Mitsubishi Plastics, Inc.) subjected to a corona treatment was bonded to the surface of the pressure-sensitive adhesive layer attached laminate from which the separator was peeled off, to prepare a laminate for a flexible image display device.

### <Preparation of (Meth)acrylic Polymer A5>

Except that the polymerization reaction was carried out at a mixing ratio (weight ratio) of ethyl acetate and toluene of 85/15 in the polymerization reaction for 7 hours while maintaining the liquid temperature in the flask at around 55° C., the polymerization was carried out in the same manner as in the preparation of the (meth)acrylic polymer A1.

### <Preparation of (Meth)acrylic Polymer A6>

Except that the polymerization reaction was carried out at a mixing ratio (weight ratio) of ethyl acetate and toluene of 70/30 in the polymerization reaction for 7 hours while maintaining the liquid temperature in the flask at around 55° C., the polymerization was carried out in the same manner as in the preparation of the (meth)acrylic polymer A1.

### Examples 2 to 9 and Comparative Examples 1 and 2

In Example 2, a laminate for a flexible image display device was produced in the same manner as in Example 1, except that in preparing the pressure-sensitive adhesive composition, the polymer ((meth)acrylic polymer) to be used and those other than specified were changed as shown in Tables 2 to 4.

Abbreviations in Tables 2 and 3 are as follows.

BA: n-Butyl acrylate
2EHA: 2-Ethylhexyl acrylate
AA: Acrylic acid
HBA: 4-Hydroxybutyl acrylate
HEA: 2-Hydroxyethyl acrylate
MMA: Methyl methacrylate
ACMO: Acryloyl morpholine
PEA: Phenoxyethyl acrylate

### NVP: N-vinylpyrrolidone

D 110N: Trimethylolpropane/xylylene diisocyanate adduct (trade name: TAKENATE D 110N, manufactured by Mitsui Chemicals, Inc.)
D 160N: Trimethylolpropane/hexamethylene diisocyanate (trade name: TAKENATE D 160N, manufactured by Mitsui Chemicals, Inc.)
C/L: Trimethylolpropane/tolylene diisocyanate (trade name: CORONATE L, manufactured by Nippon Polyurethane Industry Co., Ltd.)
Peroxide: Benzoyl peroxide (peroxide-based crosslinking agent, manufactured by NOF Corporation, trade name: NYPER BMT)

### [Evaluation]

### <Measurement of Weight Average Molecular Weight (Mw) of (Meth)acrylic Polymer>

The weight average molecular weight (Mw) of the obtained (meth)acrylic polymer was measured by GPC (gel permeation chromatography).
Analyzer: HLC-8120 GPC, manufactured by Tosoh Corporation
Column: G7000H_{XL}+GMH_{XL}+GMH_{XL}, manufactured by Tosoh Corporation
Column size: each 7.8 mmφ×30 cm, 90 cm in total
Column temperature: 40° C.
Flow rate: 0.8 ml/min
Injection volume: 100 μl
Eluent: Tetrahydrofuran
Detector: Differential refractometer (RI)
Standard sample: Polystyrene

### (Measurement of Thickness)

The thickness of each of the polarizer, the protective film, the pressure-sensitive adhesive layer, and the transparent base material was calculated together with measurement using a dial gauge (manufactured by Mitutoyo Corporation).

### (Measurement of Glass Transition Temperature Tg of Pressure-Sensitive Adhesive Layer)

The separator was peeled off from the surface of the pressure-sensitive adhesive layer of each of examples and comparative examples, and a plurality of pressure-sensitive adhesive layers were laminated to prepare a test sample having a thickness of about 1.5 mm. This test sample was punched out into a disk shape with a diameter of 8 mm, sandwiched between parallel plates, and the glass transition temperature was obtained from the peak top temperature of tan δ obtained from a dynamic viscoelasticity measurement under the following measurement conditions using a dynamic viscoelasticity measuring device “RSA III” (trade name) manufactured by TA Instruments Co., Ltd.

### (Measurement Conditions)

Deformation mode: twisting
Measurement temperature: −40° C. to 150° C.
Rate of temperature increase: 5° C./min

### (Folding Endurance Test)

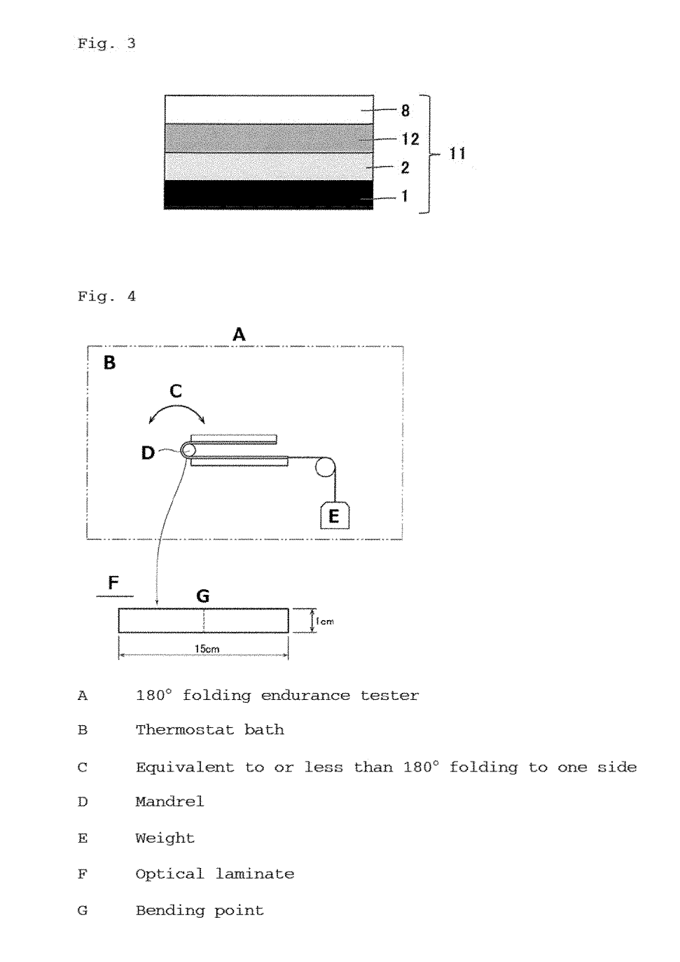

FIG. 4 is a schematic view of a 180° folding endurance tester (manufactured by Imoto Machinery Co., Ltd.). This tester has a mechanism in which a chuck on one side repeats 180° bending across a mandrel and is capable of changing a bending radius on the basis of the diameter of the mandrel. In the tester, the test is stopped when the film breaks. The laminate (5 cm×15 cm) for a flexible image display device obtained in each of examples and comparative examples was set in the tester and the folding endurance test was performed under the conditions of a temperature of −20° C., a bending angle of 180°, a bending radius of 3 mm, a bending rate of 1 second/time, and a weight of 100 g. Folding endurance was evaluated on the basis of the number of times of folding at which breakage of the laminate for a flexible image display device occurred. When the number of bending reached 200,000 times, the test was terminated.

By the folding endurance test at low temperature (−20° C.), breakage of a film such as a polarizer at a low temperature and peeling of the pressure-sensitive adhesive layer were evaluated.

As a measurement (evaluation) method, the polarizer of the laminate for a flexible image display device (see FIG. 3) was folded inward (concave side) and evaluated.

### <Presence or Absence of Breakage>

∘: No breakage
Δ: Occurrence of slight breakage at the end of the bent portion (practically no problem)
x: Occurrence of breakage on the entire surface of the bent portion (problematic in practical use)

### <Presence or Absence of Appearance Defects (Peeling)>

∘: Bending and peeling etc. are not observed.
Δ: Slight bending and peeling etc. are observed at the bent portion (practically no problem).
x: Bending and peeling etc. are observed on the entire surface of the bent portion (problematic in practical use).

TABLE 2

| (Meth)acrylic | Composition (parts by weight) | | | | | | Mw of |
|---|---|---|---|---|---|---|---|
| polymer | | | | | | Other | (meth)acrylic |
| obtained | BA | 2EHA | AA | HBA | HEA | monomers | polymer |
| A1 | 99 | | | 1 | | | 1.6 million |
| A2 | | 99.9 | | | 0.1 | | 1.75 million |
| A3 | 94.9 | | 5 | | 0.1 | | 2.2 million |
| A4 | 89.5 | | 2 | 0.5 | | ACMO (8) | 2.4 million |
| A5 | 82 | | | 1 | | NVP (1) | 1.65 million |
| | | | | | | PEA (16) | |
| A6 | 99 | | | 1 | | | 1.25 million |
| A7 | | 63 | | | 13 | NVP (15) | 0.95 million |
| | | | | | | MMA (9) | |
| A8 | 94.9 | | 5 | | 0.1 | | 2.8 million |

TABLE 3

| Kind of | | | | | | |
|---|---|---|---|---|---|---|
| pressure- | (Meth)acrylic | | | | | |
| sensitive | polymer | | | | | |
| adhesive | | Blending | Crosslinking agent | | | |
| layer | Kind | amount | D110N | D160N | C/L | Peroxide |
| 1 | A1 | 100 | 0.1 | | | 0.3 |
| 2 | A2 | 100 | | | 0.15 | |
| 3 | A3 | 100 | | | 0.6 | |
| 4 | A4 | 100 | | | 0.1 | 0.3 |
| 5 | A5 | 100 | | 0.6 | | 0.3 |
| 6 | A6 | 100 | 0.1 | | | 0.3 |
| 7 | A7 | 100 | 1 | | | |
| 8 | A8 | 100 | | | 0.6 | |

TABLE 4

| | Pressure-sensitive adhesive | | | Folding endurance | |
|---|---|---|---|---|---|
| | layer | | | test | |
| Evaluation | | Thickness | Tg | −20° C. | |
| result | Kind | [μm] | [° C.] | Breakage | Appearance |
| Example 1 | 1 | 25 | −38 | ◯ | ◯ |
| Example 2 | 5 | 25 | −23 | Δ | ◯ |
| Example 3 | 2 | 25 | −40 | ◯ | Δ |
| Example 4 | 4 | 25 | −12 | Δ | Δ |
| Example 5 | 1 | 100 | −38 | ◯ | ◯ |
| Example 6 | 1 | 10 | −38 | ◯ | Δ |
| Example 8 | 3 | 25 | −26 | Δ | ◯ |
| Example 9 | 6 | 25 | −38 | Δ | ◯ |
| Comparative | 7 | 25 | 5 | X | X |
| example 1 | | | | | |
| Comparative | 8 | 25 | −26 | X | X |
| example 2 | | | | | |

From the evaluation results in Table 4, it was confirmed that in all the examples, the folding endurance test of the laminate showed a practically acceptable level in breakage and peeling even under a low temperature environment.

On the other hand, in Comparative Example 1, since the molecular weight of the (meth)acrylic polymer used was small and the glass transition temperature of the pressure-sensitive adhesive layer was high, breakage and peeling of the laminate occurred in a low temperature environment, and it was confirmed that the laminate was not at a practical level. Further, in Comparative Example 2, since the molecular weight of the (meth)acrylic polymer used was large, it was confirmed that breakage or peeling of the laminate occurred in a low temperature environment similarly to Comparative Example 1 and thus the laminate was not at a practical level.

Although the present invention has been described with reference to the drawings concerning specific embodiments, the present invention can be modified in a number of ways other than the illustrated and described configurations. Accordingly, the present invention is not limited to the illustrated and described configurations, and the scope of the present invention is to be determined only by the appended claims and their equivalents.

### DESCRIPTION OF REFERENCE SIGNS

1 Polarizer
2 Protective film
2-1 Protective film
2-2 Protective film
3 Retardation layer
4-1 Transparent conductive film
4-2 Transparent conductive film
5-1 Base material film
5-2 Base material film
6-1 Transparent conductive layer
6-2 Transparent conductive layer
7 Spacer
8 Transparent base material
10 Organic EL display panel
10-1 Touch panel built-in organic EL display panel
11 Laminate for a flexible image display device (laminate for organic EL display device)
12 Pressure-sensitive adhesive layer
12-1 First pressure-sensitive adhesive layer
12-2 Second pressure-sensitive adhesive layer
13 Decorative printing film
20 Optical laminate
30 Touch panel
40 Window
100 Flexible image display device (organic EL display device)

1. A pressure-sensitive adhesive layer for a flexible image display device formed from a pressure-sensitive adhesive composition containing a (meth)acrylic polymer, wherein
a weight average molecular weight (Mw) of the (meth)acrylic polymer is from 1,000,000 to 2,500,000, and
a glass transition temperature (Tg) of the pressure-sensitive adhesive layer is 0° C. or less.

2. The pressure-sensitive adhesive layer for a flexible image display device according to claim 1, wherein a storage elastic modulus G′ at 25° C. is 1.0 MPa or less.

3. The pressure-sensitive adhesive layer for a flexible image display device according to claim 1, wherein an adhesive strength to a polarizing film is 5 to 40 N/25 mm.

4. A laminate for a flexible image display device, comprising the pressure-sensitive adhesive layer for a flexible image display device according to claim 1, a protective film of a transparent resin material, and a polarizer in this order.

5. A flexible image display device comprising the laminate for a flexible image display device according to claim 4 and an organic EL display panel, wherein the laminate for a flexible image display device is disposed on a viewing side of the organic EL display panel.
